(19) United States
(12) Patent Application Publication
(10) Pub. No.: US 2026/0245640 A1
(43) Pub. Date: Aug. 20, 2026

(54) MEMORY DEVICE AND ERASE METHOD THEREOF

(71) Applicant: Winbond Electronics Corp., Taichung City (TW)

(72) Inventor: Pil-Sang Ryoo, Hsinchu (TW)

(73) Assignee: Winbond Electronics Corp., Taichung City (TW)

(21) Appl. No.: 19/054,927

(22) Filed: Feb. 17, 2025

(51) Int. Cl. G11C 16/34; G11C 16/16; G11C 16/30

(52) U.S. Cl. CPC G11C 16/344; G11C 16/16; G11C 16/30

(57) ABSTRACT

A memory device includes a memory array and a memory controller. The memory array includes a plurality of erase units that are formed in a plurality of semiconductor wells corresponding to the plurality of erase units. The memory controller is coupled to the memory array and is configured to perform an erase operation to erase an erase unit corresponding to a semiconductor well of the memory array. The memory controller is configured to bias the semiconductor well with a first well bias voltage and a second well bias voltage during the erase operation, wherein the first well bias voltage is different from the second well bias voltage.

### BACKGROUND

### Technical Field

The disclosure relates to an over erase prevention technique, and more particularly relates to a memory device and an erase method thereof that may suppress over-erased memory cells in the memory device.

### Description of Related Art

In a flash memory device, memory cells are erased in unit of an erase unit having a specific size. When an erase operation is performed on an erase unit, some memory cells are erased successfully faster than other memory cells. In other words, each erase unit may have slow erase memory cells (i.e., slow bits) and fast erase memory cells (i.e., fast bits) distributed randomly in each erase unit. However, regardless of the fast erase memory cells or slow erase memory cells in the erase unit, a same erase voltage is applied to all memory cells in the erase unit until the erase operation on the erase unit is completed. Accordingly, when the slow erase memory cells reach to a target erase voltage, the fast erase memory cells have been over erased. As a result, the erase operation may result in many over-erased memory cells in the memory device.

The erase unit may be divided into small sectors, and the erase operation is performed sequentially sector by sector. However, the sector-by-sector erase operation is slow. Furthermore, since an erase verification is performed sequentially, if the slow erase memory cells are located at the former address range of the erase unit and the fast erase memory cells are located at the latter address range of the erase unit, the fast erase memory cells still would be over erased at the end of the erase operation.

It is desirable for a novel design of a memory device and an erase method thereof that are capable of suppress over-erased memory cells in the memory device.

### SUMMARY

In some embodiments of the disclosure, a memory device includes a memory array and a memory controller. The memory array includes a plurality of erase units that are formed in a plurality of semiconductor wells corresponding to the plurality of erase units. The memory controller is coupled to the memory array and is configured to perform an erase operation to erase an erase unit corresponding to a semiconductor well of the memory array. The memory controller is configured to bias the semiconductor well with a first well bias voltage and a second well bias voltage during the erase operation, wherein the first well bias voltage is different from the second well bias voltage.

In accordance with the above embodiments, an erase method of a memory device comprising a memory array and a memory controller is provided. The erase method includes steps of biasing, by the memory controller, a first well bias voltage to a top well pickup region of a semiconductor well corresponding to an erase unit of the memory array during an erase operation; and biasing, by the memory controller, a second well bias voltage to a bottom well pickup region of the semiconductor well corresponding to the erase unit of the memory array during the erase operation. The first well bias voltage is different from the second well bias voltage.

In some embodiments, a semiconductor well corresponding to an erase unit of a memory device is biased by a first well bias voltage and a second well bias voltage during an erase operation. The first well bias voltage may be biased to a top well pickup region of the semiconductor well, the second well bias voltage may be biased to a bottom well pickup region of the semiconductor well, and the second well bias voltage may be less than the first well bias voltage. In this way, memory cells or memory sectors located near the top well pickup region are erase faster than the memory cells or memory sectors located near the bottom well pickup region. As such, an erase speed of the erase operation on the erase unit is controllable. Each erase unit may include a plurality of memory sectors. When a specific erase sector passes an erase verification, a flag is set on the specific erase sector and a counter voltage may be applied on word lines connected to the specific memory sector to avoid further erase in subsequent erase steps. An erase voltage is applied to the word lines connected to the memory sectors that have not passed the erase verification. In this way, the specific memory cell that has passed the erase verification will not be further erased, thereby preventing over erase. The memory controller may increase the second well bias voltage in response to a predetermined number of memory sectors have passed the verification, thereby speeding up the erase operation.

To make the above features and advantages provided in one or more of the embodiments of the disclosure more comprehensible, several embodiments accompanied with drawings are described in detail as follows.

### BRIEF DESCRIPTION OF THE DRAWINGS

FIG. 1 is a schematic diagram of a memory device in accordance with some embodiments.

FIG. 2A and FIG. 2B are schematic diagrams of an erase unit of a memory device during an erase operation in accordance with some embodiments.

FIG. 3 is a flowchart diagram of an erase method of a memory device in accordance with some embodiments.

### DESCRIPTION OF THE EMBODIMENTS

References are made in detail to the present preferred embodiments of the invention, examples of which are illustrated in the accompanying drawings. Wherever possible, the same reference numbers are used in the drawings and the description to refer to the same or like parts.

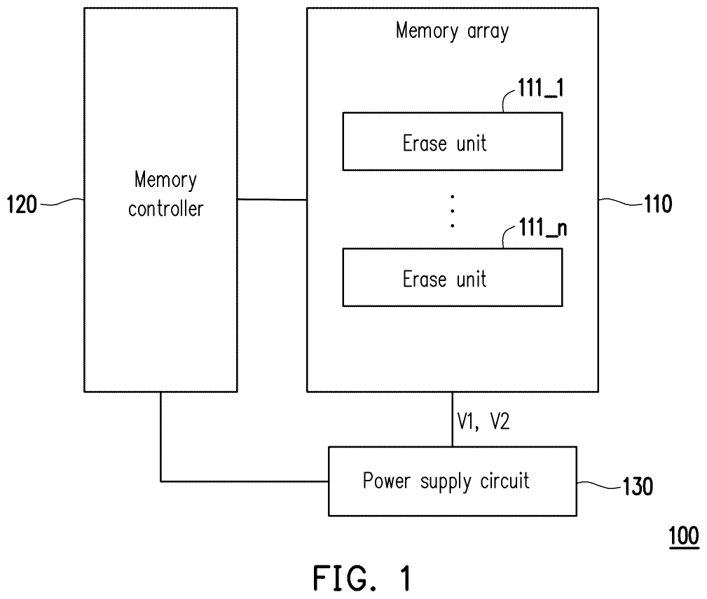

FIG. 1 illustrates a schematic diagram of a memory device 100 in accordance with some embodiments. The memory device 100 may include a memory array 110, a memory controller 120 and a power supply circuit 130. The memory array 110 may include a plurality of memory cells (not shown) being divided into a plurality of erase units 111_1 to 111_n, where n is a positive integer. Each erase unit may have a specific size (i.e., 64 KB); however, the disclosure is not limited thereto. The size of each erase unit may vary in accordance with design requirements. Each of the erase units may include a plurality of memory cells (not shown), and an erase operation is performed on the memory cells of the erase unit. The memory device 100 may be a flash memory device such as a NOR flash memory device or a NAND flash memory device. It is appreciated that the disclosure does not intend to limit the type of the memory device 100 to any specific memory type.

In some embodiments, the erase units 111_1 to 111_n of the memory array 110 are formed in semiconductor wells (not shown) corresponding to the erase units 111_1 to 111_n. In an embodiment, each erase unit is formed on a semiconductor well corresponding to the erase unit. When the erase operation is performed on the erase unit, appropriate bias voltages may be applied to the word lines, bit lines and source lines connected to the memory cells of the erase unit. In addition, during the erase operation on the erase unit, the semiconductor well corresponding to erase unit may be biased by different well bias voltages (i.e., first well bias voltage V1 and second well bias voltage V2) supplied from the power supply circuit 130. The first well bias voltage V1 may be different from the second well bias voltage V2. In some embodiments, the second well bias voltage V2 is less than the first well bias voltage V1. The semiconductor well may be a p-type semiconductor well, but the disclosure is not limited thereto. The semiconductor well may be an n-type semiconductor well in some alternative embodiments.

The power supply circuit 130 is connected to the memory array 110 and is configured to generate and supply various voltages to the memory array 110 and the memory controller 120. The power supply circuit 130 may generate and supply appropriate voltages to bias the word lines, bit lines, source lines connected to memory cells of the memory array 110 during memory operations, such as read operations, write operations and erase operations. Additionally, the power supply circuit 130 may generate and supply the first well bias voltage V1 and the second well bias voltage V2 for biasing the semiconductor well corresponding to an erase unit during an erase operation. In some embodiments, the supply circuit 130 may include a common power source (not shown) that generates both the first well bias voltage V1 and the second well bias voltage V2 for the erase operation. In some alternative embodiments, the supply circuit 130 may include a first power source (not shown) and a second power source (not shown) for generating the first well bias voltage V1 and the second well bias voltage V2, respectively.

The memory controller 120 is connected to the memory array 110 and the power supply circuit 130 and is configured to control operations of the memory array 110 and the power supply circuit 130. The memory controller 120 may control the power supply circuit 130 to generate and supply appropriate voltages for the memory operations (i.e., read operations, write operations, and erase operations) performed on the memory array 110. The memory controller 120 may control timing for applying voltages to the memory cells of the memory array 110 for performing the memory operations. It is appreciated that the disclosure does not intend to limit circuit structures of the memory array 110, the memory controller 120 and the power supply circuit 130 of the memory device 100.

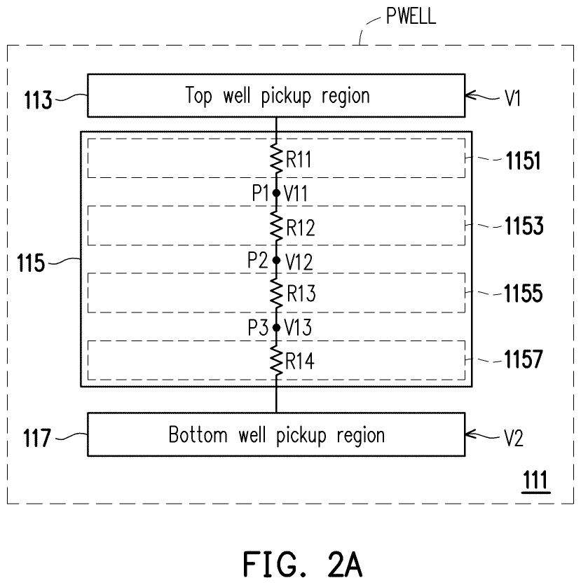

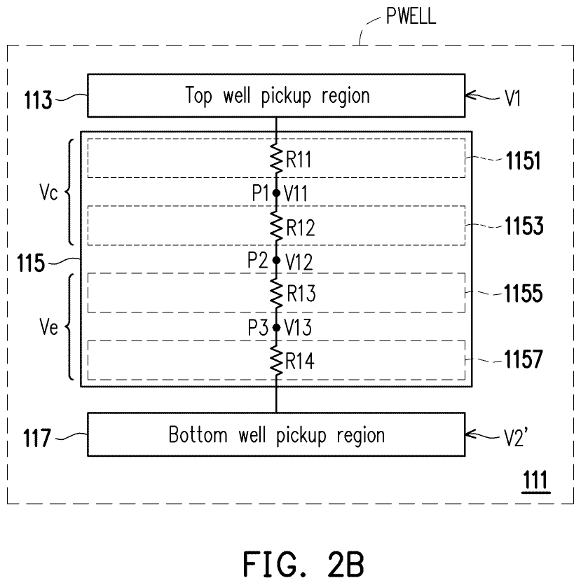

FIG. 2A illustrates a schematic diagram of an erase unit 111 during an erase operation in accordance with some embodiments. The erase unit 111 can be any one of the erase units 111_1 to 111_n of the memory array 110 in FIG. 1. The erase unit 111 may be formed in a semiconductor well PWELL which includes a top well pickup region 113, a memory area 115 and a bottom well pickup region 117. The top well pickup region 113 and the bottom well pickup region 117 may be biased by a first well bias voltage V1 and a second well bias voltage V2 respectively during the erase operation. The first well bias voltage V1 is different from the second well bias voltage V2. In some embodiments, the second well bias voltage V2 is less than the first well bias voltage V1. The memory area 115 may include a plurality of memory sectors 1151, 1153, 1155 and 1157, and each of the memory sectors 1151 to 1157 may include a plurality of memory cells. The memory sectors 1151 to 1157 may be arranged sequentially from the top well pickup region 113 to the bottom well pickup region 117.

The semiconductor well PWELL may have parasitic resistances which are represented as resistors R11, R12, R13 and R14 in FIG. 2A. The resistor R11 represents parasitic resistance of a well region corresponding to the memory sector 1151, the resistor R2 represents parasitic resistance of a well region corresponding to the memory sector 1153, the resistor R3 represents parasitic resistance of a well region corresponding to the memory sector 1155, and the resistor R4 represents parasitic resistance of a well region corresponding to the memory sector 1157. In a current path from the top well pickup region 113 to the bottom well pickup region 117, the resistors R11 to R14 cause voltage drops along the current path. The current path may include points P1, P2, P3 among the memory sectors 1151 to 1157. In details, the point P1 may be located between the memory sector 1151 and the memory sector 1153, the point P2 may be located between the memory sector 1153 and the memory sector 1155, and the point P3 may be located between the memory sector 1155 and the memory sector 1157. Due to the parasitic resistances along the current path from the top well pickup region 113 to the bottom well pickup region 117, there are voltage drops along the current path. The resistance value of the resistor R11 causes the voltage drop at the point P1; a sum of resistance values of the resistors R11 and R12 cause the voltage drop at the point P2; and a sum of the resistance values of the resistors R11, R12 and R13 cause the voltage drop at the point P3. As a result, voltages at points P1, P2, P3 may be V11, V12 and V13 respectively, in which the second bias voltage V2 is less than the voltage V13, the voltage V13 is less than the voltage V12, the voltage V12 is less than the voltage V11, and the voltage V11 is less than the first bias voltage V1.

During the erase operation on the erase unit 111, the top well pickup region 113 is biased with the first well bias voltage V1 and the bottom well pickup region 117 is biased with the second well bias voltage V2. The second well bias voltage V2 is less than the first well bias voltage V1. Due to voltage drops along the current path between the top well pickup region 113 and the bottom well pickup region 117, the well regions corresponding to the memory sectors 1151 to 1157 are biased by different voltages. For example, the well region corresponding to the memory sector 1151 may be biased with the voltage V11, the well region corresponding to the memory sector 1153 may be biased with the voltage V12, the well region corresponding to the memory sector 1155 may be biased with the voltage V13, and the well region corresponding to the memory sector 1157 may be biased with the second well bias voltage V2.

Since the voltage V11 is greater than the voltage V12, the memory cells of the memory sector 1151 may be erased faster than the memory cells of the memory sector 1153. In other words, an erase speed for erasing the memory sector 1151 may be faster than the erase speed for erasing the memory sector 1153. Similarly, the erase speed for erasing the memory sector 1153 may be faster than the erase speed for erasing the memory sector 1155, and the erase speed for erasing the memory sector 1155 may be faster than the erase speed for erasing the memory sector 1157. In this way, the memory sectors that are near the top well pickup region 113 can be erased earlier than the memory sectors that are near the bottom well pickup region 117.

In some embodiments, the memory controller 120 is further configured to perform an erase verification to determine whether memory cells in each of the memory sectors 1151 to 1157 have reached to a target erase threshold. When it determines that the memory cells of a specific memory sector have reached the target erase threshold, the specific memory sector passes the erase verification. In some embodiments, the memory controller 120 may perform the erase verification to the memory sectors arranged in an order from the top well pickup region 113 to the bottom well pickup region 117. For the erase unit 111 in FIG. 2A, the memory controller 120 performs the erase verification sequentially from the memory sector 1151 to the memory sector 1157.

In some embodiments, when the specific memory sector passes the erase verification, the memory controller 120 is configured to set a flag on the specific memory sector. The flag indicates that the specific memory sector has passed the erase verification. Meanwhile, the memory controller 120 may set a counter voltage on word lines connected to memory cells of the specific memory sector to avoid further erase performed by subsequent erase steps. The memory controller 120 may continue to perform the subsequent erase steps on the memory sectors that have not passed the erase verification by applying an erase voltage on the word lines connected to memory cells of memory sectors that have not passed the erase verification. The disclosure does not intend to limit the voltage levels of the counter voltage and the erase voltage to any specific values.

In some embodiments, in response to determining that a predetermined number of memory sectors in the erase unit 111 have passed the erase verification, the memory controller 120 may adjust a voltage level of the second well bias voltage V2 being applied to the bottom well pickup region 117. The memory controller 120 may also adjust a voltage level of the first well bias voltage V1 depending on requirements. The predetermined number of memory sectors may be set to be a half of total number of the memory sectors in the erase unit 111, but the disclosure is not limited thereto.

FIG. 2B illustrates a schematic diagram of the erase unit 111 when the predetermined number of memory sectors have passed the erase verification during an erase operation in accordance with some embodiments. The same elements in FIG. 2A and FIG. 2B are illustrated by same reference numbers. Referring to FIG. 2B, it assumes that the memory sectors 1151 and 1153 have passed the erase verification, and the memory sectors 1155 and 1157 have not passed the erase verification. The memory controller 120 may set the flag for the memory sectors 1151 and 1153 indicating that these memory sectors have passed the erase verification. Meanwhile, the memory controller 120 may apply the counter voltage Vc to the word lines connected to the memory sectors 1151 and 1153 to avoid further erase on these memory sectors. The memory controller 120 may apply the erase voltage Ve on the word lines connected to the memory sectors 1155 and 1157 to continue the erase on memory sectors 1155 and 1157.

As shown in FIG. 2B, when the predetermined number of memory sectors have passed the erase verification, the memory controller 120 may adjust the second well bias voltage V2 to be a voltage V2'. The voltage V2′ is greater than the voltage V2, resulting in the erase speed for erasing the memory sectors 1155 and 1157 being speeded up. In some embodiments, the voltage V2′ that is biased to the bottom well pickup region 117 may be set to be substantially equal as the voltage V1 that is biased to the top well pickup region 113. In this way, the overall erase speed of the erase operation on the erase unit 111 may be improved while over erase is prevented. In this way, the memory device 100 may reduce over erase risk of the erase operation performed on the erase unit with randomly located slow and fast erase memory cells (or low/fast erase bits).

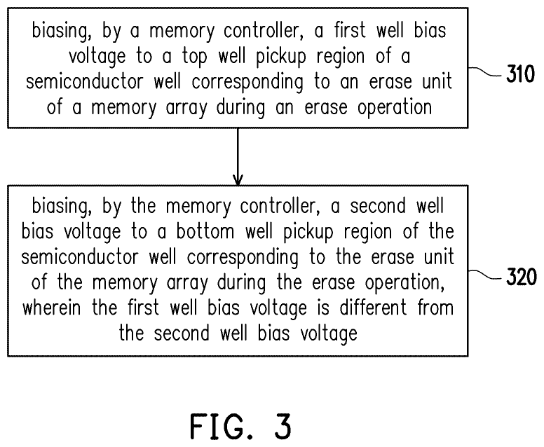

FIG. 3 illustrates a flowchart diagram of an erase method adapted to a memory device (i.e., memory device 100 in FIG. 1) in accordance with some embodiments. In block 310, the memory controller of the memory device may bias a first well bias voltage to a top well pickup region of a semiconductor well corresponding to an erase unit of a memory array during an erase operation. As shown in FIG. 2A and FIG. 3, the memory controller may bias the first well bias voltage V1 to the top well pickup region 113 of a semiconductor well PWELL corresponding to the erase unit 111 of the memory array during the erase operation. In block 320, the memory controller may bias a second well bias voltage to a bottom well pickup region of the semiconductor well corresponding to the erase unit of the memory array during the erase operation. The first well bias voltage is different from the second well bias voltage. As shown in FIG. 2A and FIG. 3, the memory controller 120 may bias the second well bias voltage V2 to the bottom well pickup region 117 of the semiconductor well PWELL corresponding to the erase unit 111 of the memory array during the erase operation. The second well bias voltage V2 is different from the first well bias voltage V1.

In accordance with the embodiments of the disclosure, a memory array of a memory device may include an erase unit formed in semiconductor well. During an erase operation on the erase units, a memory controller of the memory device may bias the semiconductor well corresponding to the erase unit with a first well bias voltage and a second well bias voltage. A top well pickup region of the semiconductor well is biased by the first well bias voltage, and a bottom well pickup region of the semiconductor well is biased by the second well bias voltage. The second well bias voltage may be less than the first well bias voltage. In this way, erase speed on the memory cells or memory sectors in the erase unit may be controllable by setting the first well bias voltage and second well bias voltage. When a specific erase sector of the erase unit passes an erase verification, a flag is set on the specific erase sector and a counter voltage may be applied on word lines connected to the specific memory sector to avoid further erase in subsequent erase steps. Accordingly, over erase risk on the specific memory cell that has passed the erase verification can be prevented. The memory controller may further increase the second well bias voltage in response to a predetermined number of memory sectors have passed the verification, thereby speeding up the erase operation. The memory device may suppress over erased memory cells in the memory array even if there are fast erase memory cells and slow erase memory cells randomly distributed in erase units of the memory array.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a memory array, comprising a plurality of erase units that are formed in a plurality of semiconductor wells corresponding to the plurality of erase units; and
a memory controller, configured to perform an erase operation to erase an erase unit corresponding to a semiconductor well of the memory array,
wherein the memory controller is configured to bias the semiconductor well with a first well bias voltage and a second well bias voltage during the erase operation, wherein the first well bias voltage is different from the second well bias voltage.

2. The memory device of claim 1, wherein
the semiconductor well corresponding to the erase unit comprises:
a top well pickup region;
a bottom well pickup region; and
a memory cell area, comprising a plurality of memory sectors arranged from the top well pickup region to the bottom well pickup region, each of the plurality of memory sectors comprises a plurality of memory cells,
wherein the memory controller is configured to bias the top well pickup region of the semiconductor well with the first well bias voltage and to bias the bottom well pickup region of the semiconductor well with the second well bias voltage.

3. The memory device of claim 2, further comprising:
a power supply circuit, connected to the memory array, configured to supply the first well bias voltage to the top well pickup region of the semiconductor well and to supply the second well bias voltage to the bottom well pickup region of the semiconductor well during the erase operation.

4. The memory device of claim 3, wherein the first well bias voltage and the second well bias voltage are supplied by a common power source of the power supply circuit.

5. The memory device of claim 3, wherein
the first well bias voltage is supplied by a first power source of the power supply circuit, and
the second well bias voltage is supplied by a second power source of the power supply circuit different from the power source.

6. The memory device of claim 2, wherein
the second well bias voltage is less than the first well bias voltage.

7. The memory device of claim 2, wherein
each of the plurality of memory sectors in the memory cell area is biased by a well bias voltage, and
wherein the well bias voltage is generated in accordance with a voltage drop from the first well bias voltage or the second well bias voltage.

8. The memory device of claim 7, wherein
the memory sectors of the memory cell area correspond to a plurality of well regions, and
the well regions are biased by different voltages during the erase operation due to voltage drops along a current path between the first well pickup region and the second well pickup region.

9. The memory device of claim 8, wherein
each of the well regions has a parasitic resistance, and
parasitic resistances of the well regions cause the voltage drops along the current path between the first well pickup region and the second well pickup region.

10. The memory device of claim 2, wherein the memory controller is further configured to:
perform an erase verification to the erase unit to verify whether the erase operation is performed successfully on each of the plurality of memory sectors in the memory cell area;
set a flag on at least one memory sector that has passed the erase verification; and
set a counter voltage on word-lines connected to the at least one memory sector that has passed the erase verification; and
set a word-line erasing voltage on the word-lines connected to memory sectors that have not passed the erase verification.

11. The memory device of claim 10, wherein the memory controller is further configured to:
determine whether a pre-defined number of memory sectors among the plurality of memory sectors of the semiconductor well has passed the erase verification; and
set the second well bias voltage to be a third well bias voltage that is greater than the second well bias voltage.

12. The memory device of claim 7, wherein the third well bias voltage is substantially same as the first well bias voltage.

13. An erase method of a memory device comprising a memory array and a memory controller, the erase method comprising:
biasing, by the memory controller, a first well bias voltage to a top well pickup region of a semiconductor well corresponding to an erase unit of the memory array during an erase operation; and
biasing, by the memory controller, a second well bias voltage to a bottom well pickup region of the semiconductor well corresponding to the erase unit of the memory array during the erase operation,
wherein the first well bias voltage is different from the second well bias voltage.

14. The erase method of claim 13, further comprising:
supplying, by a power supply circuit of the memory device, the first well bias voltage to the top well pickup region of the semiconductor well during the erase operation; and
supplying, by the power supply circuit of the memory device, the second well bias voltage to the bottom well pickup region of the semiconductor well during the erase operation.

15. The erase method of claim 13, wherein
the second well bias voltage is less than the first well bias voltage.

16. The erase method of claim 13, wherein the semiconductor well corresponding to the erase unit comprises:
the top well pickup region;
the bottom well pickup region; and
a memory cell area, comprising a plurality of memory sectors arranged from the top well pickup region to the bottom well pickup region,
wherein each of the plurality of memory sectors comprises a plurality of memory cells, each of the plurality of memory sectors in the memory cell area is biased by a well bias voltage, and the well bias voltage is generated in accordance with a voltage drop from the first well bias voltage or the second well bias voltage.

17. The erase method of claim 16, wherein
the memory sectors of the memory cell area correspond to a plurality of well regions,
the well regions are biased by different voltages during the erase operation due to voltage drops along a current path between the first well pickup region and the second well pickup region,
each of the well regions has a parasitic resistance, and
parasitic resistances of the well regions cause the voltage drops along the current path between the first well pickup region and the second well pickup region.

18. The erase method of claim 13, further comprising:
performing an erase verification to the erase unit to verify whether the erase operation is performed successfully on each of the plurality of memory sectors in the memory cell area;
setting a flag on at least one memory sector that has passed the erase verification; and
setting a counter voltage on word-lines connected to the at least one memory sector that has passed the erase verification; and
setting a word-line erasing voltage on the word-lines connected to memory sectors that have not passed the erase verification.

19. The erase method of claim 18, further comprising:
determining whether a pre-defined number of memory sectors among the plurality of memory sectors of the semiconductor well has passed the erase verification; and
setting the second well bias voltage to be a third well bias voltage that is greater than the second well bias voltage.

20. The erase method of claim 19, wherein the third well bias voltage is substantially same as the first well bias voltage.
